(19) United States
(12) Patent Application Publication
(10) Pub. No.: US 2023/0246590 A1
(43) Pub. Date: Aug. 3, 2023

(54) SOLAR POWER GENERATION APPARATUS

(71) Applicants: Japan Display Inc., Tokyo (JP); OSAKA UNIVERSITY, Osaka (JP)

(72) Inventors: Junji KOBASHI, Tokyo (JP); Shinichiro OKA, Tokyo (JP); Yasushi TOMIOKA, Tokyo (JP); Hiroyuki YOSHIDA, Suita-shi (JP)

(73) Assignees: Japan Display Inc., Tokyo (JP); OSAKA UNIVERSITY, Osaka (JP)

(21) Appl. No.: 18/193,726

(22) Filed: Mar. 31, 2023

Related U.S. Application Data
(63) Continuation of application No. PCT/JP2021/032803, filed on Sep. 7, 2021.

(30) Foreign Application Priority Data
Oct. 2, 2020 (JP) 2020-167869

(51) Int. Cl. H02S 40/22; G02B 5/30

(52) U.S. Cl. CPC H02S 40/22; G02B 5/3016

(57) ABSTRACT

According to one embodiment, a solar power generation apparatus includes an optical waveguide that includes a first main surface, a second main surface, and a lower side surface, an optical element that faces the second main surface, includes cholesteric liquid crystal, and reflects at least a part of ultraviolet ray of incident light from the first main surface toward the optical waveguide, and a solar cell that faces the lower side surface. The optical element includes a reflective surface angled with respect to a boundary surface between the optical waveguide and the optical element. An inclination angle of the reflective surface with respect to the boundary surface is an acute angle toward the solar cell.

### CROSS-REFERENCE TO RELATED APPLICATIONS

This application is a Continuation application of PCT Application No. PCT/JP2021/032803, filed Sep. 7, 2021 and based upon and claiming the benefit of priority from Japanese Patent Application No. 2020-167869, filed Oct. 2, 2020, the entire contents of all of which are incorporated herein by reference.

### FIELD

Embodiments described herein relate generally to a solar power generation apparatus.

### BACKGROUND

In recent years, various transparent solar cells have been proposed. For example, a display device with a solar cell in which a transparent dye-sensitized solar cell is arranged on a surface of a display device has been proposed.

### BRIEF DESCRIPTION OF THE DRAWINGS

FIG. 1 is a cross-sectional view schematically illustrating a solar power generation apparatus 100 of the present embodiment.

FIG. 2 is a cross-sectional view schematically illustrating a structure of an optical element 3.

FIG. 3 is a plan view schematically illustrating the solar power generation apparatus 100.

FIG. 4 is a cross-sectional view schematically illustrating an optical element 3 according to Modified Example 1.

FIG. 5 is a cross-sectional view schematically illustrating an optical element 3 according to Modified Example 2.

FIG. 6 is a cross-sectional view schematically illustrating main parts of the solar power generation apparatus 100 according to a first embodiment.

FIG. 7 is a cross-sectional view schematically illustrating the solar power generation apparatus 100 according to a first configuration example.

FIG. 8 is a cross-sectional view illustrating a state in which visible light V and infrared ray I are transmitted in the first configuration example.

FIG. 9 is a cross-sectional view schematically illustrating the solar power generation apparatus 100 according to a second configuration example.

FIG. 10 is a cross-sectional view schematically illustrating the solar power generation apparatus 100 according to a third configuration example.

FIG. 11 is a cross-sectional view schematically illustrating main parts of the solar power generation apparatus 100 according to a second embodiment.

FIG. 12 is a cross-sectional view schematically illustrating the solar power generation apparatus 100 according to a fourth configuration example.

FIG. 13 is a cross-sectional view illustrating a state in which visible light V and ultraviolet ray U are transmitted in the fourth configuration example.

FIG. 14 is a cross-sectional view schematically illustrating the solar power generation apparatus 100 according to a fifth configuration example.

FIG. 15 is a cross-sectional view schematically illustrating the solar power generation apparatus 100 according to a sixth configuration example.

FIG. 16A is a cross-sectional view schematically illustrating the solar power generation apparatus 100 according to a seventh configuration example.

FIG. 16B is a cross-sectional view schematically illustrating a solar power generation apparatus 100 according to a modified example.

FIG. 17 is a cross-sectional view illustrating a state in which visible light V is transmitted in the seventh configuration example.

FIG. 18 is a cross-sectional view illustrating a state in which ultraviolet ray U is selectively reflected in the seventh configuration example.

FIG. 19 is a cross-sectional view schematically illustrating the solar power generation apparatus 100 according to an eighth configuration example.

FIG. 20A is a cross-sectional view schematically illustrating a solar power generation apparatus 100 according to a modified example.

FIG. 20B is a cross-sectional view schematically illustrating a solar power generation apparatus 100 according to a modified example.

FIG. 21 is a cross-sectional view schematically illustrating the solar power generation apparatus 100 according to a ninth configuration example.

FIG. 22 is a cross-sectional view schematically illustrating the solar power generation apparatus 100 according to a tenth configuration example.

### DETAILED DESCRIPTION

An object of the embodiment is to provide a solar power generation apparatus capable of efficiently generating power.

In general, according to one embodiment, a solar power generation apparatus, comprises: an optical waveguide that includes a first main surface, a second main surface opposed to the first main surface, and a lower side surface located on a floor side; an optical element that faces the second main surface, includes cholesteric liquid crystal, and reflects at least a part of ultraviolet ray of incident light from the first main surface toward the optical waveguide; and a solar cell that faces the lower side surface and receives the ultraviolet ray to generate power, wherein the optical element includes a reflective surface angled with respect to a boundary surface between the optical waveguide and the optical element, and an inclination angle of the reflective surface with respect to the boundary surface is an acute angle toward the solar cell.

According to another embodiment, a solar power generation apparatus comprises: an optical waveguide that includes a first main surface, a second main surface opposed to the first main surface, and an upper side surface located on a ceiling side; an optical element that faces the second main surface, includes cholesteric liquid crystal, and reflects at least a part of infrared ray of incident light from the first main surface toward the optical waveguide; and a solar cell that faces the upper side surface and receives the infrared ray to generate power, wherein the optical element includes a reflective surface angled with respect to a boundary surface between the optical waveguide and the optical element, and an inclination angle of the reflective surface with respect to the boundary surface is an acute angle toward the solar cell.

According to yet another embodiment, a solar power generation apparatus comprises: an optical waveguide that includes a first main surface, a second main surface opposed to the first main surface, a lower side surface located on a floor side, and an upper side surface located on a ceiling side; an optical element group that faces the second main surface; a first solar cell that faces the lower side surface and receives ultraviolet rays of incident light to generate power; and a second solar cell that faces the upper side surface and receives infrared rays of incident light to generate power, wherein the optical element group includes: a first optical element that includes cholesteric liquid crystal with a first spiral pitch and reflects at least part of incident light via the optical waveguide toward the optical waveguide; and a second optical element that overlaps the first optical element, includes cholesteric liquid crystal with a second spiral pitch different from the first spiral pitch, and reflects at least a part of incident light via the optical waveguide toward the optical waveguide, the first optical element includes a first reflective surface angled with respect to a boundary surface between the optical waveguide and the optical element group, an inclination angle of the first reflective surface with respect to the boundary surface is an acute angle toward the first solar cell, the second optical element includes a second reflective surface angled with respect to the boundary surface, and an inclination angle of the second reflective surface with respect to the boundary surface is an acute angle toward the second solar cell.

According to an embodiment, it is possible to provide a solar power generation apparatus capable of efficiently generating power.

Embodiments will be described hereinafter with reference to the accompanying drawings. The disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

Note that, in order to make the descriptions more easily understandable, some of the drawings illustrate an X axis, a Y axis and a Z axis orthogonal to each other. A direction along the Z axis is referred to as a first direction A1, a direction along the Y axis is referred to as a second direction A2 and a direction along the X axis is referred to as a third direction A3. The first direction A1, the second direction A2 and the third direction A3 are orthogonal to each other. A plane defined by the X axis and the Y axis is referred to as an X-Y plane, a plane defined by the X axis and the Z axis is referred to as an X-Z plane, and a plane defined by the Y axis and the Z axis is referred to as a Y-Z plane.

### Basic Configuration Example

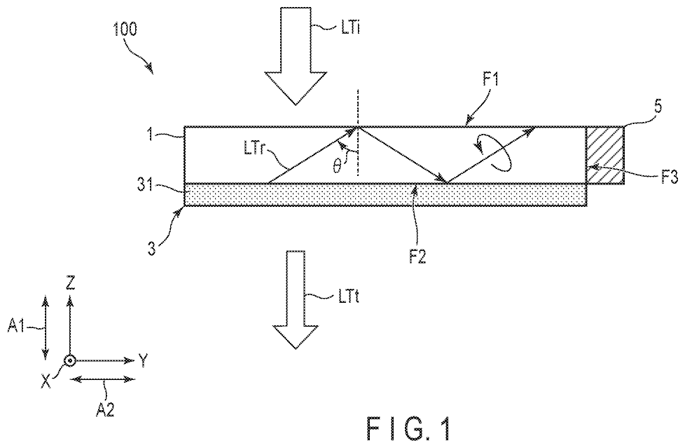

FIG. 1 is a cross-sectional view schematically illustrating a solar power generation apparatus 100 of the present embodiment. The solar power generation apparatus 100 includes an optical waveguide 1, an optical element 3, and a solar cell 5.

The optical waveguide 1 is made of a transparent member that transmits light, for example, a transparent glass plate or a transparent synthetic resin plate. The optical waveguide 1 may be made of, for example, a transparent synthetic resin plate having flexibility. The optical waveguide 1 may have any shape. For example, the optical waveguide 1 may have a curved shape. The refractive index of the optical waveguide 1 is larger than the refractive index of air, for example. The optical waveguide 1 functions as, for example, a window glass of a building, a windshield of a vehicle, or the like.

In the present specification, “light” includes visible light and invisible light. For example, the lower limit wavelength of the visible light range is 360 nm or more and 400 nm or less, and the upper limit wavelength of the visible light range is 760 nm or more and 830 nm or less. The visible light includes a first component (blue component) in a first wavelength band (for example, 400 nm to 500 nm), a second component (green component) in a second wavelength band (for example, 500 nm to 600 nm), and a third component (red component) in a third wavelength band (for example, 600 nm to 700 nm). The invisible light includes an ultraviolet ray in a wavelength band shorter than the first wavelength band and an infrared ray in a wavelength band longer than the third wavelength band.

In the present specification, “transparent” is preferably colorless and transparent. However, “transparent” may be translucent or colored transparent.

The optical waveguide 1 is formed in a flat plate shape along the X-Y plane, and includes a first main surface F1, a second main surface F2, and a side surface F3. The first main surface F1 and the second main surface F2 are surfaces substantially parallel to the X-Y plane, and face each other in a first direction A1. The side surface F3 is a surface extending along the first direction A1. In the example illustrated in FIG. 1, the side surface F3 is a surface substantially parallel to the X-Z plane, but the side surface F3 includes a surface substantially parallel to the Y-Z plane.

The optical element 3 faces the second main surface F2 of the optical waveguide 1 in the first direction A1. The optical element 3 reflects at least a part of light LTi incident from the first main surface F1 toward the optical waveguide 1. In one example, the optical element 3 includes a liquid crystal layer 31 that reflects at least one of first circularly polarized light and second circularly polarized light in the direction opposite to the first circularly polarized light of the incident light LTi. The first circularly polarized light and the second circularly polarized light reflected by the optical element 3 are invisible light such as ultraviolet ray and infrared ray, for example, but may be visible light. In the present specification, “reflection” in the optical element 3 involves diffraction inside the optical element 3.

Note that the optical element 3 may have flexibility, for example. In addition, the optical element 3 may be in contact with the second main surface F2 of the optical waveguide 1, or a transparent layer such as an adhesive layer may be interposed between the optical element 3 and the optical waveguide 1. The refractive index of the layer interposed between the optical element 3 and the optical waveguide 1 is preferably substantially equal to the refractive index of the optical waveguide 1.

The optical element 3 is configured as a thin film. For example, there may be a case where the optical element 3 separately formed in a film shape is adhered to the optical waveguide 1, or there may be a case where a material is directly applied to the optical waveguide 1 to form the film-shaped optical element 3.

The solar cell 5 faces the side surface F3 of the optical waveguide 1 in a second direction A2. The solar cell 5 receives light and converts energy of the received light into electric power. That is, the solar cell 5 generates power by the received light. The type of the solar cell is not particularly limited, and the solar cell 5 is, for example, a silicon-based solar cell, a compound solar cell, an organic solar cell, a perovskite solar cell, or a quantum dot solar cell. Examples of the silicon-based solar cell include a solar cell including amorphous silicon, a solar cell including polycrystalline silicon, and the like. The solar cell 5 shown here is an example of a light receiving element. Another example of the light receiving element is an optical sensor. That is, the solar cell 5 may be replaced with an optical sensor.

Next, in the example illustrated in FIG. 1, the operation of the solar power generation apparatus 100 will be described.

The light LTi incident on the first main surface F1 of the optical waveguide 1 is, for example, solar light. That is, the light LTi includes ultraviolet rays and infrared rays in addition to visible light.

In the example illustrated in FIG. 1, in order to facilitate understanding, it is assumed that the light LTi is incident substantially perpendicular to the optical waveguide 1. The incident angle of the light LTi with respect to the optical waveguide 1 is not particularly limited. For example, the light LTi may be incident on the optical waveguide 1 at a plurality of incident angles different from each other.

The light LTi enters the inside of the optical waveguide 1 from the first main surface F1 and enters the optical element 3 via the second main surface F2. Then, the optical element 3 reflects a part of light LTr of the light LTi toward the optical waveguide 1 and the solar cell 5, and transmits the other part of light LTt. Here, optical losses such as absorption in the optical waveguide 1 and the optical element 3 are ignored. The light LTr reflected by the optical element 3 corresponds to, for example, first circularly polarized light having a predetermined wavelength. The light LTt transmitted through the optical element 3 includes second circularly polarized light having a predetermined wavelength and light having a wavelength different from the predetermined wavelength. The predetermined wavelength here is, for example, ultraviolet rays or infrared rays. Note that, in the present specification, the circularly polarized light may be strictly circularly polarized light or may be circularly polarized light approximate to elliptically polarized light.

The optical element 3 reflects the first circularly polarized light toward the optical waveguide 1 at an approach angle θ that satisfies the optical waveguide condition in the optical waveguide 1. The approach angle θ here corresponds to an angle equal to or larger than a critical angle θc at which total reflection occurs inside the optical waveguide 1. The approach angle θ indicates an angle with respect to a perpendicular line orthogonal to the optical waveguide 1.

The light LTr enters the inside of the optical waveguide 1 from the second main surface F2, and propagates through the inside of the optical waveguide 1 while repeating reflection in the optical waveguide 1.

The solar cell 5 receives the light LTr emitted from the side surface F3 and generates power.

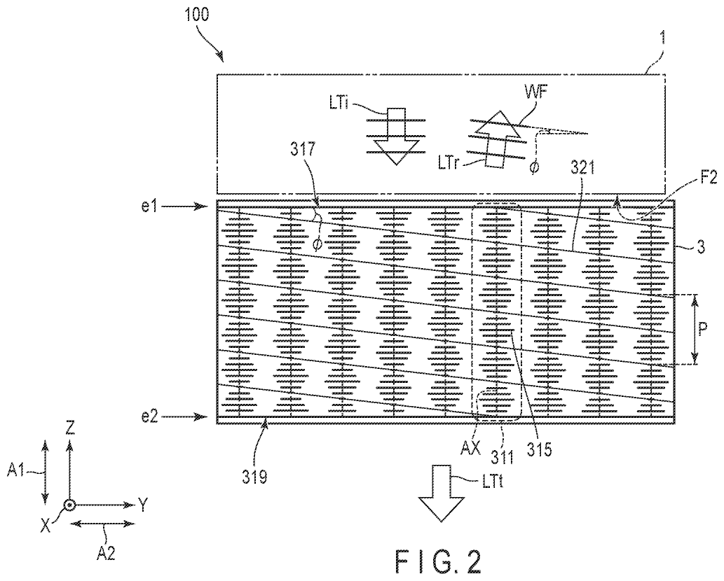

FIG. 2 is a cross-sectional view schematically illustrating a structure of an optical element 3. Note that the optical waveguide 1 is indicated by a two-dot chain line.

The optical element 3 has a plurality of spiral structures 311. Each of the plurality of spiral structures 311 extends along the first direction A1. That is, a spiral axis AX of each of the plurality of spiral structures 311 is substantially perpendicular to the second main surface F2 of the optical waveguide 1. The spiral axis AX is substantially parallel to the first direction A1. Each of the plurality of spiral structures 311 has a spiral pitch P. The spiral pitch P indicates one period (360 degrees) of the spiral. Each of the plurality of spiral structures 311 includes a plurality of elements 315. The plurality of elements 315 are spirally stacked along the first direction A1 while swirling.

The optical element 3 includes a first boundary surface 317 facing the second main surface F2, a second boundary surface 319 opposite to the first boundary surface 317, and a plurality of reflective surfaces 321 between the first boundary surface 317 and the second boundary surface 319. The first boundary surface 317 is a surface on which the light LTi transmitted through the optical waveguide 1 and emitted from the second main surface F2 is incident on the optical element 3. Each of the first boundary surface 317 and the second boundary surface 319 is substantially perpendicular to the spiral axis AX of the spiral structure 311. Each of first boundary surface 317 and second boundary surface 319 is substantially parallel to optical waveguide 1 (or second main surface F2).

The first boundary surface 317 includes an element 315 located at one end e1 of both ends of the spiral structure 311. The first boundary surface 317 is located at a boundary between the optical waveguide 1 and the optical element 3. The second boundary surface 319 includes an element 315 located at the other end e2 of both ends of the spiral structure 311. The second boundary surface 319 is located at the boundary between the optical element 3 and the air layer.

In the example illustrated in FIG. 2, the plurality of reflective surfaces 321 are substantially parallel to each other. The reflective surface 321 is angled with respect to the first boundary surface 317 and the optical waveguide 1 (or the second main surface F2), and has a substantially planar shape extending in a certain direction. The reflective surface 321 selectively reflects a part of the light LTr of the light LTi incident from the first boundary surface 317 according to Bragg's law. Specifically, the reflective surface 321 reflects the light LTr such that a wave front WF of the light LTr is substantially parallel to the reflective surface 321. More specifically, the reflective surface 321 reflects the light LTr according to an inclination angle φ of the reflective surface 321 with respect to the first boundary surface 317.

The reflective surface 321 can be defined as follows. That is, the refractive index of light (for example, circularly polarized light) of a predetermined wavelength selectively reflected by the optical element 3 gradually changes as the light travels inside the optical element 3. Therefore, Fresnel reflection gradually occurs in the optical element 3. Then, Fresnel reflection occurs most strongly at a position where the refractive index felt by light changes most greatly in the plurality of spiral structures 311. That is, the reflective surface 321 corresponds to a surface on which Fresnel reflection occurs most strongly in the optical element 3.

In the plurality of spiral structures 311, the orientation directions of the respective elements 315 of the spiral structures 311 adjacent in the second direction A2 are different from each other. Further, the spatial phases of the spiral structures 311 adjacent to each other in the second direction A2 among the plurality of spiral structures 311 are different from each other. The reflective surface 321 corresponds to a surface in which the orientation directions of the elements 315 are aligned or a surface in which the spatial phases are aligned (equal phase surface). That is, each of the plurality of reflective surfaces 321 is angled with respect to the first boundary surface 317 or the optical waveguide 1.

Note that the shape of the reflective surface 321 is not limited to the planar shape as illustrated in FIG. 2, and may be a concave or convex curved surface shape, and is not particularly limited. In addition, a part of the reflective surface 321 may have unevenness, the inclination angle φ of the reflective surface 321 may not be uniform, or the plurality of reflective surfaces 321 may not be regularly aligned. The reflective surface 321 having an arbitrary shape can be configured according to the spatial phase distribution of the plurality of spiral structures 311.

In the present embodiment, the spiral structure 311 is cholesteric liquid crystal. Each of the elements 315 corresponds to a liquid crystal molecule. In FIG. 2, for simplification of the drawing, one element 315 represents liquid crystal molecules facing the average orientation direction among a plurality of liquid crystal molecules located in the X-Y plane.

The cholesteric liquid crystal, which is the spiral structure 311, reflects circularly polarized light in the same swirling direction as the swirling direction of the cholesteric liquid crystal in the light having a predetermined wavelength λ included in a selective reflection band Δλ. For example, when the swirling direction of the cholesteric liquid crystal is clockwise, clockwise circularly polarized light in the light having the predetermined wavelength λ is reflected, and counterclockwise circularly polarized light is transmitted. Similarly, when the swirling direction of the cholesteric liquid crystal is counterclockwise, counterclockwise circularly polarized light in the light having the predetermined wavelength λ is reflected, and clockwise circularly polarized light is transmitted.

When the spiral pitch of the cholesteric liquid crystal is denoted by P, the refractive index of the liquid crystal molecules for extraordinary light is denoted by ne, and the refractive index of the liquid crystal molecules for ordinary light is denoted by no, in general, the selective reflection band Δλ of the cholesteric liquid crystal for perpendicularly incident light is represented by “no*P to ne*P”. Specifically, the selective reflection band Δλ of the cholesteric liquid crystal changes in accordance with the inclination angle φ of the reflective surface 321, the incident angle on the first boundary surface 317, and the like with respect to the range of “no*P to ne*P”.

When the optical element 3 is formed of cholesteric liquid crystal, for example, the optical element 3 is formed as a thin film. For example, the optical element 3 is formed by polymerizing the plurality of spiral structures 311. Specifically, the optical element 3 is formed by polymerizing a plurality of elements (liquid crystal molecules) 315. For example, the plurality of liquid crystal molecules are polymerized by irradiating the plurality of liquid crystal molecules with light.

Alternatively, the optical element 3 is formed by controlling the alignment of a polymer liquid crystal material exhibiting a liquid crystal state at a predetermined temperature or a predetermined concentration so as to form a plurality of spiral structures 311 in the liquid crystal state, and then transferring the polymer liquid crystal material to a solid while maintaining the alignment.

In the optical element 3, the adjacent spiral structures 311 are bonded to each other while maintaining the orientation of the spiral structure 311, that is, while maintaining the spatial phase of the spiral structure 311 by polymerization or transition to a solid. As a result, in the optical element 3, the orientation direction of each liquid crystal molecule is fixed.

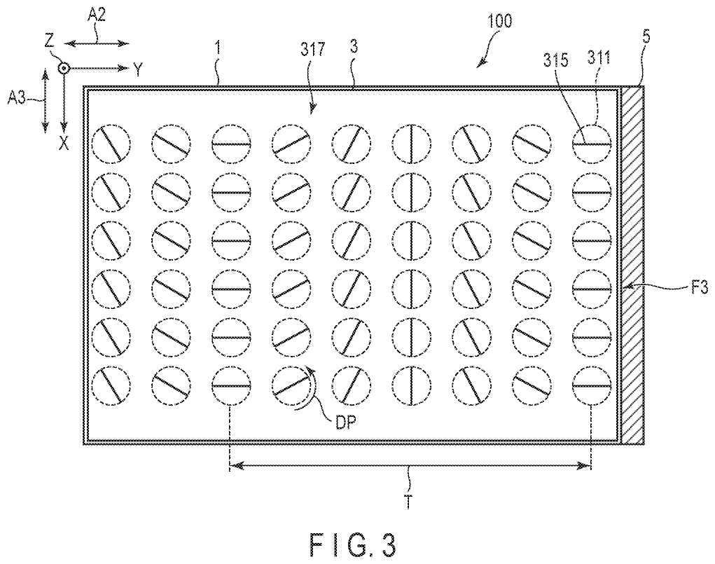

FIG. 3 is a plan view schematically illustrating the solar power generation apparatus 100.

FIG. 3 illustrates an example of the spatial phase of the spiral structure 311. The spatial phase illustrated here is illustrated as the orientation direction of the element 315 positioned at the first boundary surface 317 among the elements 315 included in the spiral structure 311.

For each of the spiral structures 311 arranged along the second direction A2, the orientation directions of the elements 315 located at the first boundary surface 317 are different from each other. That is, the spatial phase of the spiral structure 311 at the first boundary surface 317 is different along the second direction A2.

On the other hand, for each of the spiral structures 311 arranged along the third direction A3, the orientation directions of the elements 315 located at the first boundary surface 317 substantially coincide. That is, the spatial phases of the spiral structure 311 at the first boundary surface 317 substantially coincide with each other in the third direction A3.

In particular, when attention is paid to the spiral structures 311 arranged in the second direction A2, the orientation direction of each element 315 differs by a certain angle. That is, in the first boundary surface 317, the orientation directions of the plurality of elements 315 arranged along the second direction A2 change linearly. Therefore, the spatial phases of the plurality of spiral structures 311 arranged along the second direction A2 linearly change along the second direction A2. As a result, as in the optical element 3 illustrated in FIG. 2, the reflective surface 321 angled with respect to the first boundary surface 317 and the optical waveguide 1 is formed. Here, “linearly change” indicates that, for example, the amount of change in the orientation direction of the element 315 is represented by a linear function.

Here, the orientation direction of the element 315 corresponds to a long axis direction of the liquid crystal molecules in the X-Y plane when the spiral structure 311 is cholesteric liquid crystal.

Here, as illustrated in FIG. 3, in the first boundary surface 317, the interval between the two spiral structures 311 when the orientation direction of the element 315 is changed by 180 degrees along the second direction A2 is defined as a period T of the spiral structure 311. In FIG. 3, DP indicates the swirling direction of the element 315. The inclination angle φ of the reflective surface 321 illustrated in FIG. 2 is appropriately set by the period T and the spiral pitch P.

### Modified Example 1

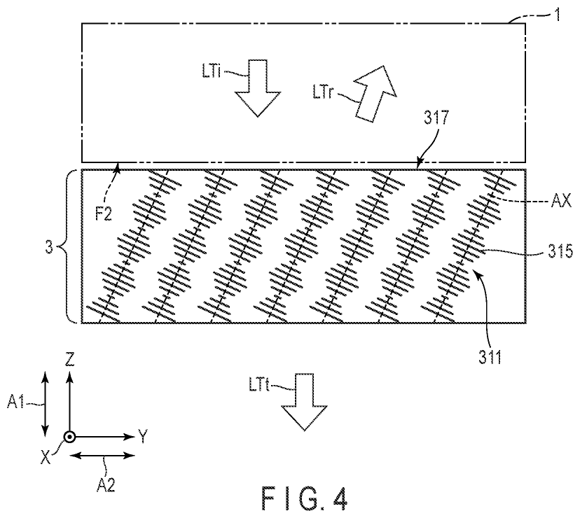

FIG. 4 is a cross-sectional view schematically illustrating an optical element 3 according to Modified Example 1.

Modified Example 1 illustrated in FIG. 4 is different from the configuration example illustrated in FIG. 2 in that the spiral axis AX of the spiral structure 311 is angled with respect to the optical waveguide 1, the second main surface F2, or the first boundary surface 317. In Modified Example 1 illustrated in FIG. 4, the spatial phases of the spiral structure 311 in the first boundary surface 317 or the X-Y plane substantially coincide with each other. In addition, the spiral structure 311 according to Modified Example 1 has the same characteristics as those of the spiral structure 311 according to the above-described configuration example.

In such Modified Example 1, the optical element 3 reflects a part of the light LTr in the light LTi incident through the optical waveguide 1 at a reflection angle corresponding to the inclination of the spiral axis AX, and transmits the other part of the light LTt.

### Modified Example 2

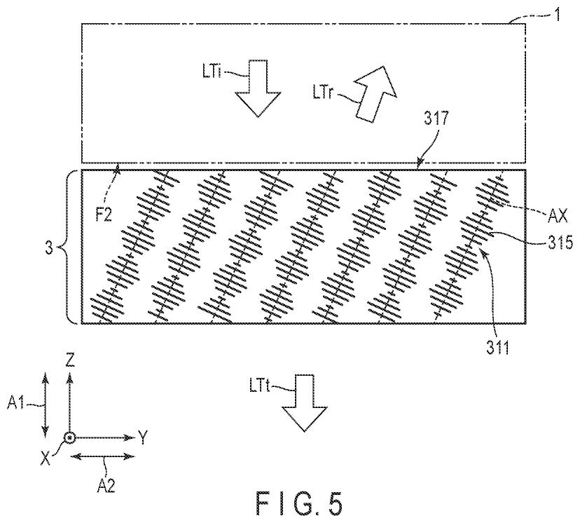

FIG. 5 is a cross-sectional view schematically illustrating an optical element 3 according to Modified Example 2.

Modified Example 2 illustrated in FIG. 5 is different from Modified Example 1 illustrated in FIG. 4 in that the spatial phase of the spiral structure 311 in the first boundary surface 317 or the X-Y plane is different along the second direction A2. In addition, the spiral structure 311 according to Modified Example 1 has the same characteristics as those of the spiral structure 311 according to the above-described configuration example.

In such Modified Example 2, the optical element 3 reflects a part of the light LTr in the light LTi incident through the optical waveguide 1 at a reflection angle corresponding to the inclination of the spiral axis AX, and transmits the other part of the light LTt.

Some embodiments are described below. In each embodiment, a description will be given assuming that the spiral structure is cholesteric liquid crystal.

### First Embodiment

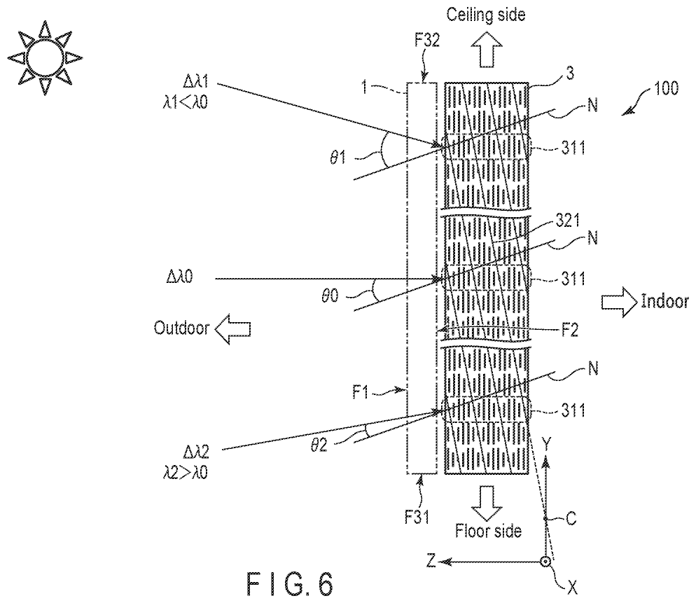

FIG. 6 is a cross-sectional view schematically illustrating main parts of the solar power generation apparatus 100 according to a first embodiment. Note that the optical waveguide 1 is indicated by a two-dot chain line.

Here, it is assumed that the solar power generation apparatus 100 is attached to a building, and the solar power generation apparatus 100 is installed such that a Y-axis in the drawing is along a vertical line. At this time, the optical waveguide 1 as a window glass is disposed on the outdoor side, and the optical element 3 is disposed on the indoor side. In a case where the window glass is configured as multilayer glass such as paired glass or triple glass, the optical waveguide 1 is disposed on the most outdoor side.

In such an optical waveguide 1, the first main surface F1 is located on the outdoor side, and the second main surface F2 is located on the indoor side. Here, the vertically lower side, that is, the floor side is referred to as “lower”, and the vertically upper side, that is, the ceiling side is referred to as “upper”.

The optical waveguide 1 includes a lower side surface F31 and an upper side surface F32 as a part of the side surface F3. The lower side surface F31 corresponds to a side surface located below the horizon when a person indoors observes the outdoors via the solar power generation apparatus 100. The upper side surface F32 corresponds to a side surface located above the horizon when a person indoors observes the outdoors via the solar power generation apparatus 100.

In the optical element 3, the reflective surface 321 is angled with respect to the Y-axis. In the example illustrated in FIG. 6, the continuous reflective surface 321 is inclined so as to be close to the indoor side on the floor side and to be close to the outdoor side on the ceiling side. Alternatively, in the reflective surface 321 intersecting the Y-axis, the reflective surface 321 on the floor side of the intersection C between the reflective surface 321 and the Y-axis extends toward the indoor side, and the reflective surface 321 on the ceiling side of the intersection C extends toward the outdoor side. Therefore, a normal line N of the reflective surface 321 is inclined upward on the indoor side and inclined downward on the outdoor side.

Here, a case where the selective reflection band of the cholesteric liquid crystal 311 in the optical element 3 is set to a band Δλ0 including a center wavelength λ0 will be considered. Note that the selective reflection band Δλ0 is a band closer to the ultraviolet ray as the spiral pitch P is smaller, and is a band closer to the infrared ray as the spiral pitch P is larger. The relationship between the spiral pitch P and the selective reflection band Δλ0 also depends on the incident angle of light on the reflective surface 321 and the angle of the reflective surface 321 with respect to the interface between the optical waveguide 1 and the optical element 3. As an example, the selective reflection band Δλ0 when the spiral pitch P is 150 nm to 250 nm is a band of ultraviolet ray, the selective reflection band Δλ0 when the spiral pitch P is 250 nm to 500 nm is a band of visible light, and the selective reflection band Δλ0 when the spiral pitch P is 500 nm to 900 nm is a band of infrared ray.

When the light in the selective reflection band Δλ0 is perpendicularly incident on the solar power generation apparatus 100, an incident angle of the reflective surface 321 with respect to the normal line N is θ0. When the light in the selective reflection band Δλ0 is incident on the solar power generation apparatus 100 from an oblique direction, the selective reflection band is shifted. Here, the angle of the reflective surface 321 is set such that the selective reflection band shifts to the short wavelength side when the incident angle with respect to the normal line N of the reflective surface 321 is larger than θ0, and the selective reflection band shifts to the long wavelength side when the incident angle with respect to the normal line N of the reflective surface 321 is smaller than θ0. When the incident angle of the reflective surface 321 with respect to the normal line N is below the normal line N, the selective reflection band shifts to the short wavelength side.

Therefore, when light is incident on the solar power generation apparatus 100 from obliquely above like solar light, an incident angle 61 with respect to the normal line N is larger than the incident angle θ0. In this case, a center wavelength λ1 of a selective reflection band Δλ1 of the light incident on the solar power generation apparatus 100 is shorter than the center wavelength λ0. That is, the selective reflection band Δλ1 is shifted to a shorter wavelength side than the selective reflection band Δλ0.

In addition, when light is incident on the solar power generation apparatus 100 from obliquely downward, an incident angle θ2 with respect to the normal line N is smaller than the incident angle θ0. In this case, a center wavelength λ2 of a selective reflection band Δλ2 of the light incident on the solar power generation apparatus 100 is longer than the center wavelength λ0. That is, the selective reflection band Δλ2 is shifted to the longer wavelength side than the selective reflection band Δλ0.

In the solar power generation apparatus 100 to which the optical element 3 illustrated in FIG. 6 is applied, the selective reflection band Δλ0 is desirably set to the band of ultraviolet ray. That is, the solar light used for power generation is incident on the solar power generation apparatus 100 from obliquely above. In addition, the selective reflection band Δλ0 of the optical element 3 shifts to the short wavelength side with respect to light incident obliquely upward. Therefore, when the selective reflection band Δλ0 is set to the band of ultraviolet ray, visible light (particularly, a blue component) is hardly included in the selective reflection band when the selective reflection band Δλ0 is shifted to the short wavelength side. As a result, colorshift of the surface of the solar power generation apparatus 100 can be suppressed. In addition, coloring of the light transmitted through the solar power generation apparatus 100 can be suppressed. Therefore, degradation in appearance quality as a transparent window glass is suppressed.

### First Embodiment—First Configuration Example

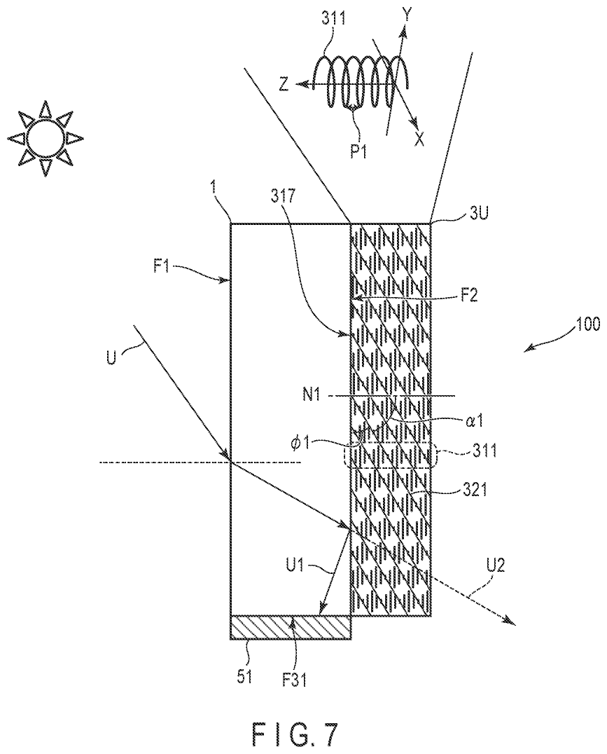

FIG. 7 is a cross-sectional view schematically illustrating the solar power generation apparatus 100 according to a first configuration example.

In the solar power generation apparatus 100 of the first configuration example illustrated in FIG. 7, a solar cell 51 is disposed so as to face the lower side surface F31 of the optical waveguide 1. An optical element 3U described in the first embodiment exerts a function equivalent to that of the optical element 3 described above. In the optical element 3U, the reflective surface 321 is angled with respect to the first boundary surface 317. An inclination angle φ1 of the reflective surface 321 with respect to the first boundary surface 317 is an acute angle toward the solar cell 51 side (or below a normal line N1 of the first boundary surface 317). Alternatively, an angle α1 formed by the normal line N1 of the first boundary surface 317 and the reflective surface 321 is an acute angle below the normal line N1.

FIG. 7 schematically illustrates the cholesteric liquid crystal 311 swirled in the first swirling direction in an enlarged manner with respect to the cholesteric liquid crystal 311 included in the optical element 3U. The cholesteric liquid crystal 311 has a first spiral pitch P1 along a Z-axis to reflect the ultraviolet ray U as a selective reflection band. In the optical element 3U, the first spiral pitch P1 of the cholesteric liquid crystal 311 is constant with almost no change along the Z-axis.

For example, the cholesteric liquid crystal 311 is configured to reflect the first circularly polarized light U1 of the ultraviolet ray U in the selective reflection band. As described above, when the first swirling direction is counterclockwise, the cholesteric liquid crystal 311 reflects counterclockwise first circularly polarized light U1 of the ultraviolet ray U. In addition, when the first swirling direction is clockwise, the cholesteric liquid crystal 311 reflects clockwise first circularly polarized light U1 of the ultraviolet ray U.

In the solar power generation apparatus 100 of the first configuration example, when the solar light is incident from the obliquely upper direction, the ultraviolet ray U of the solar light enters the inside of the optical waveguide 1 from the first main surface F1, and enters the optical element 3U through the second main surface F2. Then, the optical element 3U reflects the first circularly polarized light U1 of the ultraviolet ray U on the reflective surface 321 toward the optical waveguide 1 and the solar cell 51. The optical element 3U transmits second circularly polarized light U2 of the ultraviolet ray U. The reflected first circularly polarized light U1 enters the inside of the optical waveguide 1 from the second main surface F2, and propagates downward inside the optical waveguide 1 while repeating reflection in the optical waveguide 1. The solar cell 51 receives the ultraviolet ray U emitted from the lower side surface F31 and generates power.

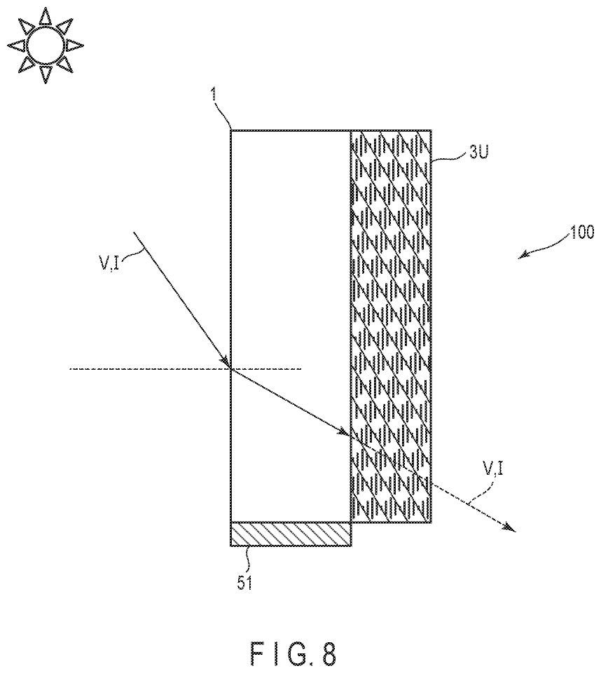

Next, visible light V and infrared ray I included in solar light will be described with reference to FIG. 8. The visible light V and the infrared ray I are incident on the optical element 3U after transmitting through the optical waveguide 1. Since the first spiral pitch P1 is set such that the selective reflection band Δλ0 becomes the ultraviolet ray U as illustrated in FIG. 7, the optical element 3U transmits the visible light V and the infrared ray I with almost no reflection and diffraction. Therefore, in the first configuration example, the visible light V and the infrared ray I are not used for power generation.

According to such a first configuration example, it is possible to efficiently generate power using the ultraviolet ray U. The solar power generation apparatus 100 transmits each of the first component (blue component), the second component (green component), and the third component (red component), which are main components of the visible light V. Therefore, coloring of the light transmitted through the solar power generation apparatus 100 can be suppressed. In addition, it is possible to suppress a degradation in transmittance of the visible light V in the solar power generation apparatus 100.

### First Embodiment—Second Configuration

### Example

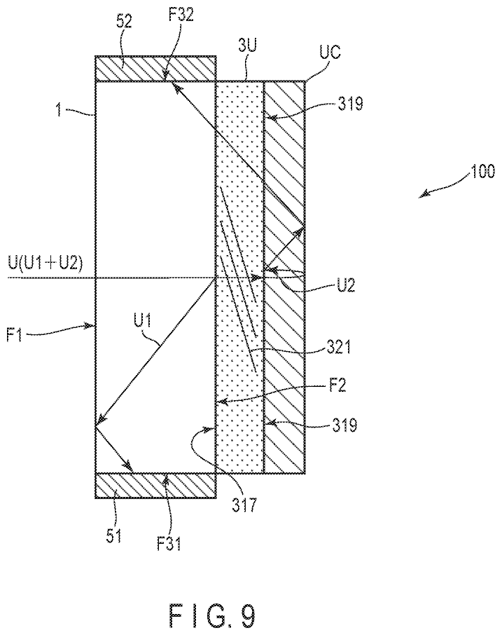

FIG. 9 is a cross-sectional view schematically illustrating the solar power generation apparatus 100 according to a second configuration example.

The second configuration example illustrated in FIG. 9 is different from the first configuration example illustrated in FIG. 7 in that the solar power generation apparatus 100 includes an ultraviolet cut layer UC. The ultraviolet cut layer UC is disposed so as to face the indoor side surface of the optical element 3U, that is, the second boundary surface 319. That is, the optical element 3U is located between the optical waveguide 1 and the ultraviolet cut layer UC.

The solar power generation apparatus 100 of the second configuration example includes a solar cell 52 in addition to the solar cell 51. The solar cell 52 is disposed so as to face the upper side surface F32 of the optical waveguide 1.

In the solar power generation apparatus 100 of the second configuration example, the ultraviolet ray U including the first circularly polarized light U1 and the second circularly polarized light U2 enters the inside of the optical waveguide 1 from the first main surface F1, and enters the optical element 3U through the second main surface F2. Then, the optical element 3U reflects the first circularly polarized light U1 toward the optical waveguide 1 and the solar cell 51 on the reflective surface 321, and transmits the second circularly polarized light U2. The reflected first circularly polarized light U1 enters the inside of the optical waveguide 1 from the second main surface F2, and propagates downward inside the optical waveguide 1 while repeating reflection in the optical waveguide 1. The solar cell 51 receives the ultraviolet ray U emitted from the lower side surface F31 and generates power.

On the other hand, the second circularly polarized light U2 transmitted through the optical element 3U enters the ultraviolet cut layer UC, and enters the optical element 3U again while repeating reflection inside the ultraviolet cut layer UC. In the optical element 3U, the incident light from the first boundary surface 317 side and the incident light from the second boundary surface 319 side are reflected and diffracted in opposite directions. That is, the light incident on the optical element 3U from the ultraviolet cut layer UC is reflected on the reflective surface 321 toward the optical waveguide 1 and the solar cell 52. The reflected light enters the inside of the optical waveguide 1 from the second main surface F2, and propagates upward inside the optical waveguide 1 while repeating reflection in the optical waveguide 1. The solar cell 52 receives the ultraviolet ray U emitted from the upper side surface F32 and generates power.

According to such a second configuration example, power can be generated using not only the first circularly polarized light U1 of the ultraviolet ray U but also the second circularly polarized light U2. Further, in the solar power generation apparatus 100, it is possible to suppress the transmission of the ultraviolet ray U to the interior.

### First Embodiment—Third Configuration Example

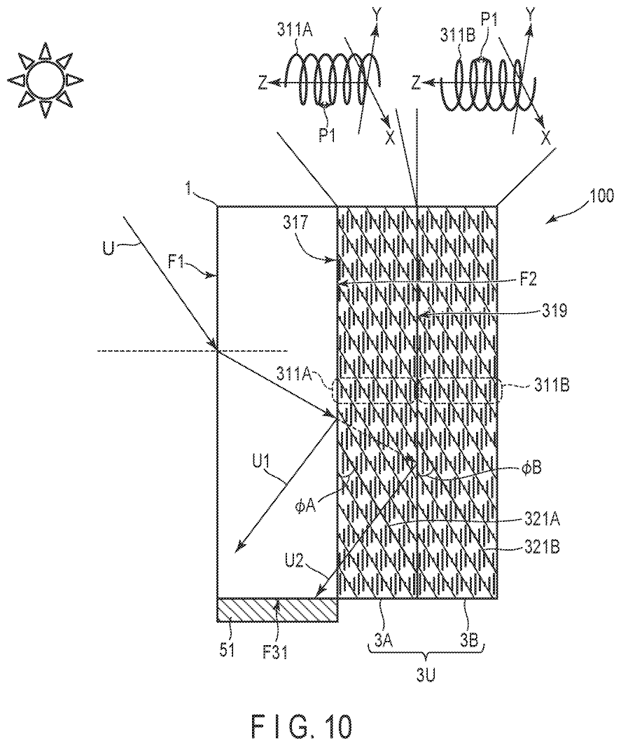

FIG. 10 is a cross-sectional view schematically illustrating the solar power generation apparatus 100 according to a third configuration example.

The third configuration example illustrated in FIG. 10 is different from the first configuration example illustrated in FIG. 7 in that the optical element 3U includes a first layer 3A having the cholesteric liquid crystal 311A swirled in the first swirling direction and a second layer 3B having the cholesteric liquid crystal 311B swirled in the second swirling direction opposite to the first swirling direction. The first layer 3A and the second layer 3B overlap each other along the Z-axis. A thin film such as an alignment film may be interposed between the first layer 3A and the second layer 3B. The first layer 3A is located between optical waveguide 1 and the second layer 3B. The first boundary surface 317 is located between the optical waveguide 1 and the first layer 3A, and the second boundary surface 319 is located between the first layer 3A and the second layer 3B.

A reflective surface 321A in the first layer 3A is angled with respect to the first boundary surface 317. An inclination angle φA of the reflective surface 321A with respect to the first boundary surface 317 is an acute angle toward the solar cell 51. As schematically illustrated in an enlarged manner, the cholesteric liquid crystal 311A included in the first layer 3A is swirled in the first swirling direction. Such a cholesteric liquid crystal 311A is configured to reflect the first circularly polarized light in the first swirling direction in the selective reflection band.

The reflective surface 321B in the second layer 3B is angled with respect to the second boundary surface 319. An inclination angle φB of the reflective surface 321B with respect to the second boundary surface 319 is an acute angle toward the solar cell 51. The inclination angle φB may be the same as or different from the inclination angle φA. That is, the reflective surface 321B may be parallel to the reflective surface 321A or may not be parallel to the reflective surface 321A. As schematically illustrated in an enlarged manner, the cholesteric liquid crystal 311B included in the second layer 3B is swirled in the second swirling direction. Such a cholesteric liquid crystal 311B is configured to reflect the second circularly polarized light in the second swirling direction in the selective reflection band.

Both the cholesteric liquid crystals 311A and 311B have a first spiral pitch P1 along the Z-axis so as to reflect the ultraviolet ray U as a selective reflection band. That is, the spiral pitches of the cholesteric liquid crystal 311A and the cholesteric liquid crystal 311B are substantially equal to each other. As a result, the cholesteric liquid crystal 311A of the first layer 3A reflects the first circularly polarized light U1 of the ultraviolet ray U, and the cholesteric liquid crystal 311B of the second layer 3B reflects the second circularly polarized light U2 of the ultraviolet ray U.

According to such a third configuration example, power can be generated using not only the first circularly polarized light U1 of the ultraviolet ray U but also the second circularly polarized light U2. Further, in the solar power generation apparatus 100, it is possible to suppress the transmission of the ultraviolet ray U to the interior.

### Second Embodiment

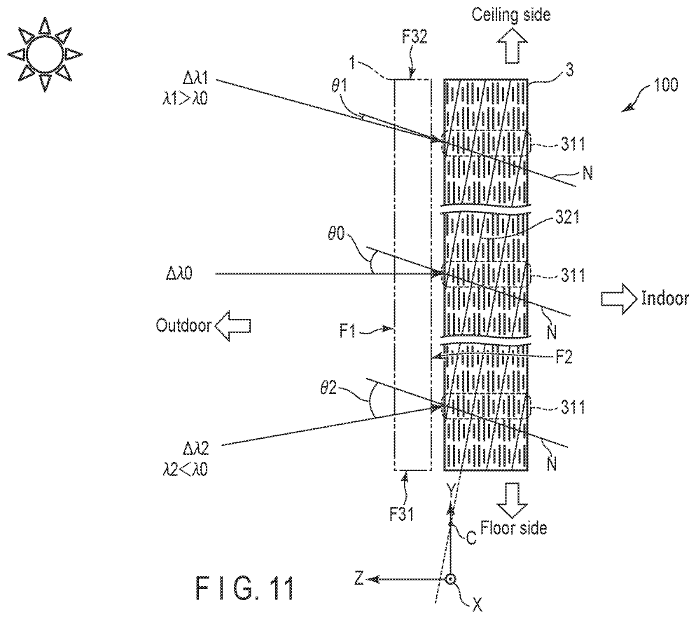

FIG. 11 is a cross-sectional view schematically illustrating main parts of the solar power generation apparatus 100 according to a second embodiment. Note that the optical waveguide 1 is indicated by a two-dot chain line.

Also in the second embodiment, similarly to the first embodiment, it is assumed that the solar power generation apparatus 100 is installed such that the Y-axis in the drawing is along a vertical line.

In the optical element 3, the reflective surface 321 is angled with respect to the Y-axis. In the example illustrated in FIG. 11, the continuous reflective surface 321 is inclined so as to be close to the outdoor side on the floor side and to be close to the indoor side on the ceiling side. Alternatively, in the reflective surface 321 intersecting the Y-axis, the reflective surface 321 on the floor side of the intersection C between the reflective surface 321 and the Y-axis extends toward the outdoor side, and the reflective surface 321 on the ceiling side of the intersection C extends toward the indoor side. Therefore, the normal line N of the reflective surface 321 is inclined upward on the outdoor side and inclined downward on the indoor side.

A case where the selective reflection band of the cholesteric liquid crystal 311 in an optical element 3 is set to the band Δλ0 including the center wavelength λ0 will be considered.

When the light in the selective reflection band Δλ0 is perpendicularly incident on the solar power generation apparatus 100, an incident angle of the reflective surface 321 with respect to the normal line N is θ0. When the light in the selective reflection band Δλ0 is incident on the solar power generation apparatus 100 from an oblique direction, the selective reflection band is shifted as in the first embodiment. Here, the angle of the reflective surface 321 is set such that the selective reflection band shifts to the short wavelength side when the incident angle with respect to the normal line N of the reflective surface 321 is larger than θ0, and the selective reflection band shifts to the long wavelength side when the incident angle with respect to the normal line N of the reflective surface 321 is smaller than θ0. When the incident angle of the reflective surface 321 with respect to the normal line N is above the normal line N, the selective reflection band shifts to the short wavelength side.

When light is incident on the solar power generation apparatus 100 from obliquely above like solar light, the incident angle 61 with respect to the normal line N is smaller than the incident angle θ0. In this case, the center wavelength λ1 of the selective reflection band Δλ1 of the light incident on the solar power generation apparatus 100 is longer than the center wavelength λ0. That is, the selective reflection band Δλ1 is shifted to the longer wavelength side than the selective reflection band Δλ0.

When light is incident on the solar power generation apparatus 100 from obliquely downward, the incident angle θ2 with respect to the normal line N is larger than the incident angle θ0. In this case, the center wavelength λ 2 of the selective reflection band Δλ2 of the light incident on the solar power generation apparatus 100 is shorter than the center wavelength λ0. That is, the selective reflection band Δλ2 is shifted to a shorter wavelength side than the selective reflection band Δλ0.

In the solar power generation apparatus 100 to which the optical element 3 illustrated in FIG. 11 is applied, the selective reflection band Δλ0 is desirably set to the band of infrared ray. That is, the solar light used for power generation is incident on the solar power generation apparatus 100 from obliquely above. In addition, the selective reflection band Δλ0 of the optical element 3 shifts to the long wavelength side with respect to light incident obliquely upward. Therefore, when the selective reflection band Δλ0 is set to the band of infrared ray, visible light (in particular, a red component) is hardly included in the selective reflection band when the selective reflection band Δλ0 is shifted to the long wavelength side. As a result, colorshift of the surface of the solar power generation apparatus 100 can be suppressed. In addition, coloring of the light transmitted through the solar power generation apparatus 100 can be suppressed. Therefore, degradation in appearance quality as a transparent window glass is suppressed.

### Second Embodiment—Fourth Configuration Example

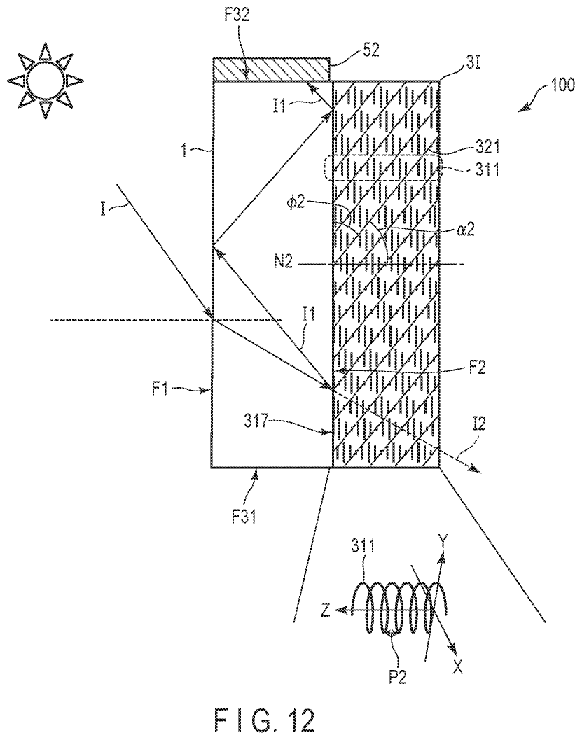

FIG. 12 is a cross-sectional view schematically illustrating the solar power generation apparatus 100 according to a fourth configuration example.

In the solar power generation apparatus 100 of the fourth configuration example illustrated in FIG. 12, the solar cell 52 is disposed so as to face the upper side surface F32 of the optical waveguide 1. An optical element 3I described in the second embodiment exerts a function equivalent to that of the optical element 3 described above. In the optical element 3I, the reflective surface 321 is angled with respect to the first boundary surface 317. An inclination angle φ2 of the reflective surface 321 with respect to the first boundary surface 317 is an acute angle toward the solar cell 52 side (or above a normal line N2 of the first boundary surface 317). Alternatively, an angle α2 formed by the normal line N2 of the first boundary surface 317 and the reflective surface 321 is an acute angle above the normal line N1.

In FIG. 12, the cholesteric liquid crystal 311 swirled in the first swirling direction is schematically illustrated in an enlarged manner with respect to the cholesteric liquid crystal 311 included in the optical element 3I. The cholesteric liquid crystal 311 has a second spiral pitch P2 along the Z-axis to reflect infrared ray I as a selective reflection band. In the optical element 3I, the second spiral pitch P2 of the cholesteric liquid crystal 311 is constant with almost no change along the Z-axis.

For example, the cholesteric liquid crystal 311 is configured to reflect first circularly polarized light I1 of the infrared ray I in the selective reflection band. As described above, when the first swirling direction is counterclockwise, the cholesteric liquid crystal 311 reflects the counterclockwise first circularly polarized light I1 of the infrared ray I. When the first swirling direction is clockwise, the cholesteric liquid crystal 311 reflects clockwise first circularly polarized light I1 of infrared ray I.

In the solar power generation apparatus 100 of the fourth configuration example, when the solar light is incident from the obliquely upper direction, the infrared ray I of the solar light enters the inside of the optical waveguide 1 from the first main surface F1, and enters the optical element 3I through the second main surface F2. Then, the optical element 3I reflects the first circularly polarized light I1 of the infrared ray I on the reflective surface 321 toward the optical waveguide 1 and the solar cell 52. The optical element 3I transmits second circularly polarized light I2 of the infrared ray I. The reflected first circularly polarized light I1 enters the inside of the optical waveguide 1 from the second main surface F2, and propagates upward inside the optical waveguide 1 while repeating reflection in the optical waveguide 1. The solar cell 52 receives the infrared ray I emitted from the upper side surface F32 and generates power.

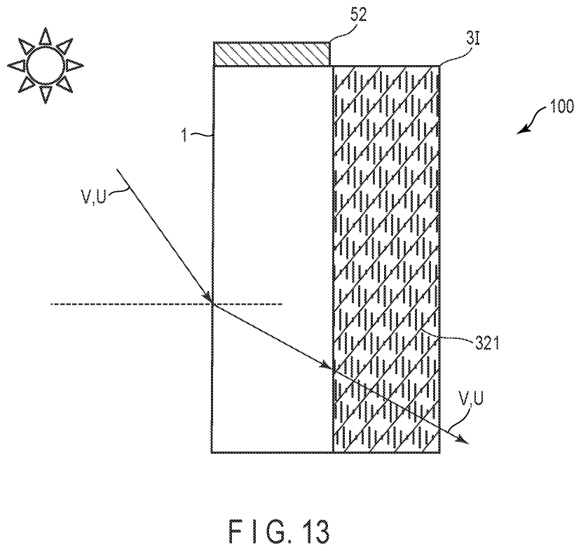

Next, visible light V and ultraviolet ray U included in solar light will be described with reference to FIG. 13. The visible light V and the ultraviolet ray U are incident on the optical element 3I after transmitting through the optical waveguide 1. Since the second spiral pitch P2 is set so as to reflect the infrared ray I as illustrated in FIG. 12, the optical element 3I transmits the visible light V and the ultraviolet ray U with almost no reflection and diffraction. Therefore, in the fourth configuration example, the visible light V and the ultraviolet ray U are not used for power generation.

According to such a fourth configuration example, it is possible to efficiently generate power using the infrared ray I. The solar power generation apparatus 100 transmits each of the first component (blue component), the second component (green component), and the third component (red component), which are main components of the visible light V. Therefore, coloring of the light transmitted through the solar power generation apparatus 100 can be suppressed. In addition, it is possible to suppress a degradation in transmittance of the visible light V in the solar power generation apparatus 100.

### Second Embodiment—Fifth Configuration Example

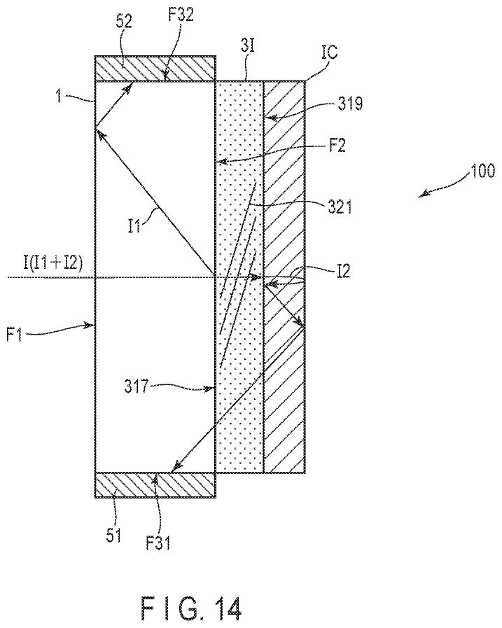

FIG. 14 is a cross-sectional view schematically illustrating the solar power generation apparatus 100 according to a fifth configuration example.

The fifth configuration example illustrated in FIG. 14 is different from the fourth configuration example illustrated in FIG. 12 in that the solar power generation apparatus 100 includes an infrared cut layer IC. The infrared cut layer IC is disposed so as to face the indoor side surface of the optical element 3I, that is, the second boundary surface 319. That is, the optical element 3I is located between the optical waveguide 1 and the infrared cut layer IC.

The solar power generation apparatus 100 of the fifth configuration example includes a solar cell 51 in addition to the solar cell 52. The solar cell 51 is disposed so as to face the lower side surface F31 of the optical waveguide 1.

In the solar power generation apparatus 100 of the fifth configuration example, the infrared ray I including the first circularly polarized light I1 and the second circularly polarized light I2 enters the inside of the optical waveguide 1 from the first main surface F1, and enters the optical element 3I through the second main surface F2. Then, the optical element 3I reflects the first circularly polarized light I1 toward the optical waveguide 1 and the solar cell 52 on the reflective surface 321, and transmits the second circularly polarized light I2. The reflected first circularly polarized light I1 enters the inside of the optical waveguide 1 from the second main surface F2, and propagates upward inside the optical waveguide 1 while repeating reflection in the optical waveguide 1. The solar cell 52 receives the infrared ray I emitted from the upper side surface F32 and generates power.

On the other hand, the second circularly polarized light I2 transmitted through the optical element 3I enters the infrared cut layer IC, and enters the optical element 3I again while repeating reflection inside the infrared cut layer IC. In the optical element 3I, the incident light from the first boundary surface 317 side and the incident light from the second boundary surface 319 side are reflected and diffracted in opposite directions. That is, the light incident on the optical element 3I from the infrared cut layer IC is reflected on the reflective surface 321 toward the optical waveguide 1 and the solar cell 51. The reflected light enters the inside of the optical waveguide 1 from the second main surface F2, and propagates downward inside the optical waveguide 1 while repeating reflection in the optical waveguide 1. The solar cell 51 receives the infrared ray I emitted from the lower side surface F31 and generates power.

According to such a fifth configuration example, power can be generated using not only the first circularly polarized light I1 of the infrared ray I but also the second circularly polarized light I2. Further, in the solar power generation apparatus 100, it is possible to suppress the transmission of the infrared ray I to the interior.

### Second Embodiment—Sixth Configuration Example

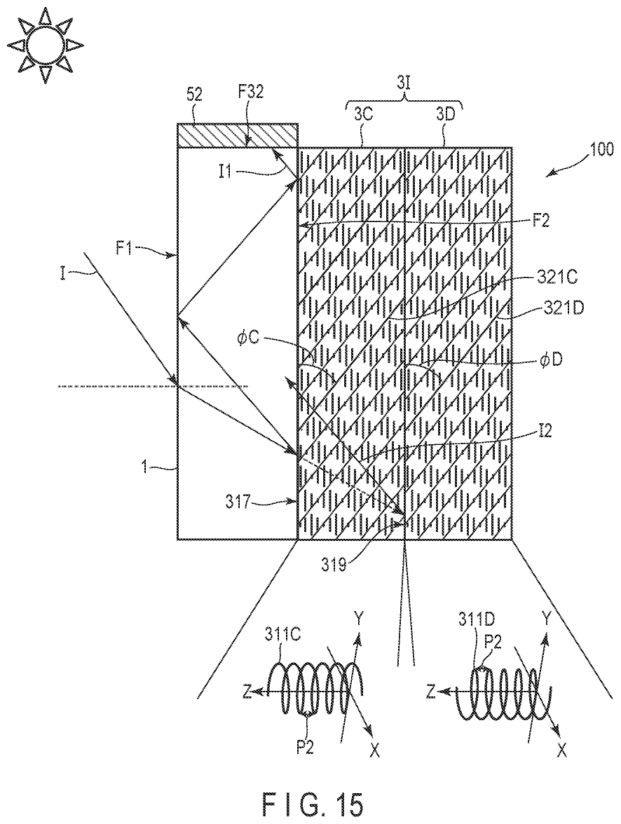

FIG. 15 is a cross-sectional view schematically illustrating the solar power generation apparatus 100 according to a sixth configuration example.

The sixth configuration example illustrated in FIG. 15 is different from the fourth configuration example illustrated in FIG. 12 in that the optical element 3I includes a first layer 3C having the cholesteric liquid crystal 311C swirled in the first swirling direction and a second layer 3D having the cholesteric liquid crystal 311D swirled in the second swirling direction. The first layer 3C and the second layer 3D overlap each other along the Z-axis. A thin film such as an alignment film may be interposed between the first layer 3C and the second layer 3D. The first layer 3C is located between the optical waveguide 1 and the second layer 3D. The first boundary surface 317 is located between the optical waveguide 1 and the first layer 3C, and the second boundary surface 319 is located between the first layer 3C and the second layer 3D.

The reflective surface 321C in the first layer 3C is angled with respect to the first boundary surface 317. An inclination angle φC of the reflective surface 321C with respect to the first boundary surface 317 is an acute angle toward the solar cell 52. As schematically illustrated in an enlarged manner, the cholesteric liquid crystal 311C included in the first layer 3C is swirled in the first swirling direction. Such a cholesteric liquid crystal 311C is configured to reflect the first circularly polarized light in the first swirling direction in the selective reflection band.

The reflective surface 321D in the second layer 3D is angled with respect to the second boundary surface 319. An inclination angle φD of the reflective surface 321D with respect to the second boundary surface 319 is an acute angle toward the solar cell 52. The inclination angle φD may be the same as or different from the inclination angle φC. That is, the reflective surface 321D may be parallel to the reflective surface 321C or may not be parallel to the reflective surface 321C. As schematically illustrated in an enlarged manner, the cholesteric liquid crystal 311D included in the second layer 3D is swirled in the second swirling direction. Such a cholesteric liquid crystal 311D is configured to reflect the second circularly polarized light in the second swirling direction in the selective reflection band.

Both the cholesteric liquid crystals 311C and 311D have a second spiral pitch P2 along the Z-axis so as to reflect the infrared ray I as a selective reflection band. That is, the spiral pitches of the cholesteric liquid crystal 311C and the cholesteric liquid crystal 311D are substantially equal to each other. As a result, the cholesteric liquid crystal 311C of the first layer 3C reflects the first circularly polarized light I1 of the infrared ray I, and the cholesteric liquid crystal 311D of the second layer 3D reflects the second circularly polarized light I2 of the infrared ray I.

According to such a sixth configuration example, power can be generated using not only the first circularly polarized light I1 of the infrared ray I but also the second circularly polarized light I2. Further, in the solar power generation apparatus 100, it is possible to suppress the transmission of the infrared ray I to the interior.

### Third Embodiment

A solar power generation apparatus 100 according to the third embodiment described below includes an optical waveguide 1, an optical element group 3G including a plurality of optical elements, a first solar cell 51 facing a lower side surface F31 of the optical waveguide 1, and a second solar cell 52 facing an upper side surface F32 of the optical waveguide 1.

The optical element group 3G includes a plurality of optical elements having different selective reflection bands. In one example, the optical element group 3G includes the first optical element 3U whose selective reflection band is the ultraviolet ray U and the second optical element 3I whose selective reflection band is the infrared ray I.

The first solar cell 51 and the second solar cell 52 desirably have different absorption wavelength peaks. In one example, the first solar cell 51 is configured to have high sensitivity to ultraviolet rays, and the second solar cell 52 is configured to have high sensitivity to infrared rays.

Hereinafter, some configuration examples will be described.

### Third Embodiment—Seventh Configuration Example

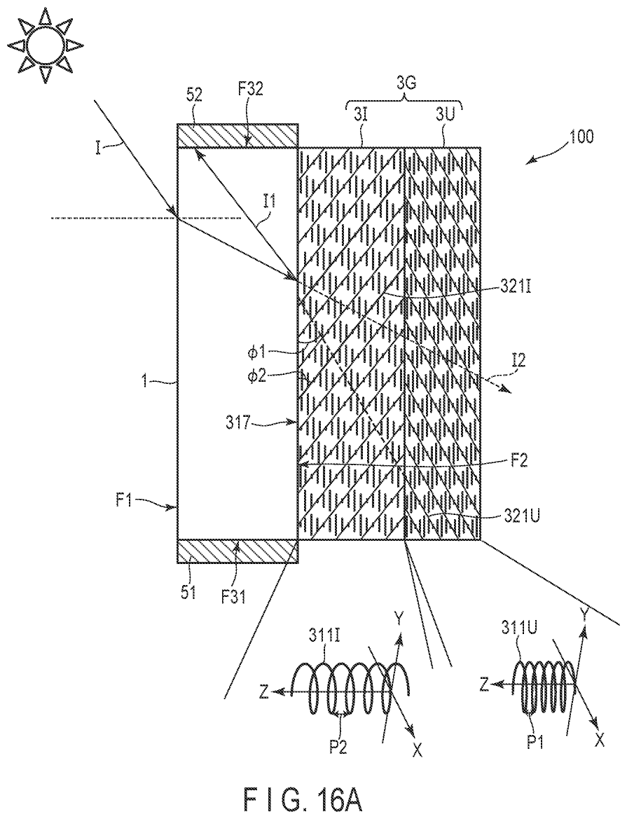

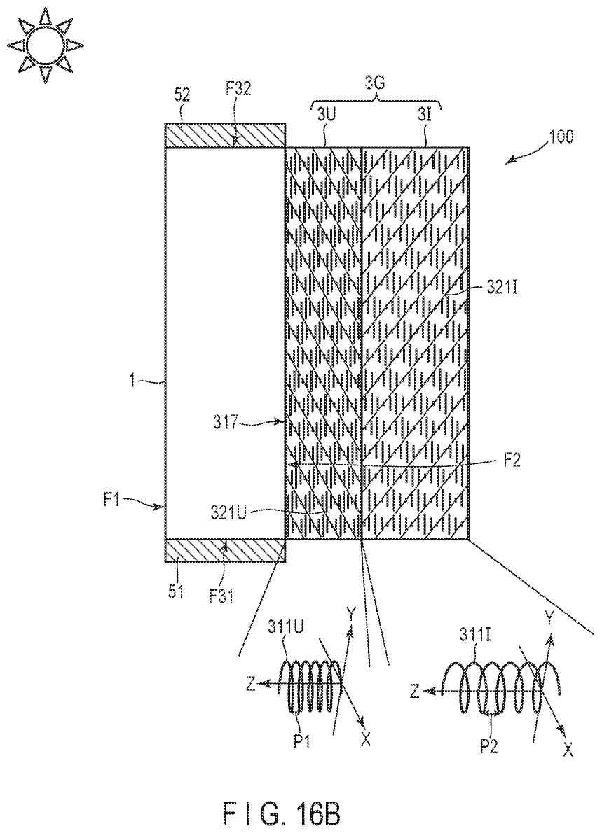

FIG. 16A is a cross-sectional view schematically illustrating the solar power generation apparatus 100 according to a seventh configuration example.

In the solar power generation apparatus 100 of the seventh configuration example, the optical element group 3G is disposed so as to face the second main surface F2. The first optical element 3U and the second optical element 3I overlap each other along the Z-axis. Note that a thin film such as an alignment film may be interposed between the first optical element 3U and the second optical element 3I. In the example illustrated in FIG. 16A, the second optical element 3I is located between the optical waveguide 1 and the first optical element 3U, but the first optical element 3U may be located between the optical waveguide 1 and the second optical element 3I as in the example illustrated in FIG. 16B. Note that the following description will be made based on the configuration illustrated in FIG. 16A.

The reflective surface 321U of the first optical element 3U is angled with respect to the first boundary surface 317 between the optical waveguide 1 and the optical element group 3G. An inclination angle φ1 of the reflective surface 321U with respect to the first boundary surface 317 is an acute angle toward the first solar cell 51. The cholesteric liquid crystal 311U included in the first optical element 3U has a first spiral pitch P1 along the Z-axis so as to swirl, for example, in the first swirling direction and reflect the ultraviolet ray U as a selective reflection band. For example, the cholesteric liquid crystal 311U is configured to reflect the first circularly polarized light U1 of the ultraviolet ray U in the selective reflection band.

The reflective surface 321I of the second optical element 3I is angled with respect to the first boundary surface 317. An inclination angle φ2 of the reflective surface 321I with respect to the first boundary surface 317 is an acute angle toward the second solar cell 52. The cholesteric liquid crystal 311I included in the second optical element 3I swirls, for example, in the first swirling direction, and has a second spiral pitch P2 along the Z-axis so as to reflect the infrared ray I as the selective reflection band. The second spiral pitch P2 is different from the first spiral pitch P1, and the second spiral pitch P2 is greater than the first spiral pitch P1 (P1<P2). For example, the cholesteric liquid crystal 311I is configured to reflect the first circularly polarized light I1 of the infrared ray I in the selective reflection band.

Note that details of the first optical element 3U are as described in the first embodiment, and details of the second optical element 3I are as described in the second embodiment.

The first solar cell 51 is disposed so as to face the lower side surface F31, and the second solar cell 52 is disposed so as to face the upper side surface F32. Each of the first solar cell 51 and the second solar cell 52 is, for example, a silicon-based solar cell. In one example, the first solar cell 51 includes amorphous silicon, and the second solar cell 52 includes polycrystalline silicon.

When the polycrystalline silicon and the amorphous silicon are compared, peaks of absorption wavelengths are different from each other. That is, the peak of the absorption wavelength of amorphous silicon is around 450 nm, and the peak of the absorption wavelength of polycrystalline silicon is around 700 nm. That is, amorphous silicon has a higher absorption index of ultraviolet ray U than polycrystalline silicon. Therefore, the first solar cell 51 is suitable for power generation by the ultraviolet ray U. In addition, polycrystalline silicon has a higher absorption index of infrared ray I than amorphous silicon. Therefore, the second solar cell 52 is suitable for power generation by the infrared ray I. The configuration of each of the first solar cell 51 and the second solar cell 52 is not limited thereto.

In the solar power generation apparatus 100 of the seventh configuration example, when the solar light is incident from the obliquely upper direction, the infrared ray I of the solar light enters the inside of the optical waveguide 1 from the first main surface F1, and enters the second optical element 3I through the second main surface F2. Then, the second optical element 3I reflects the first circularly polarized light I1 of the infrared ray I on the reflective surface 321I toward the optical waveguide 1 and the second solar cell 52. The second optical element 3I transmits the second circularly polarized light I2 of the infrared ray I. The first optical element 3U also transmits the second circularly polarized light I2. The reflected first circularly polarized light I1 enters the inside of the optical waveguide 1 from the second main surface F2, and propagates upward inside the optical waveguide 1 while repeating reflection in the optical waveguide 1. The second solar cell 52 receives the infrared ray I emitted from the upper side surface F32 and generates power.

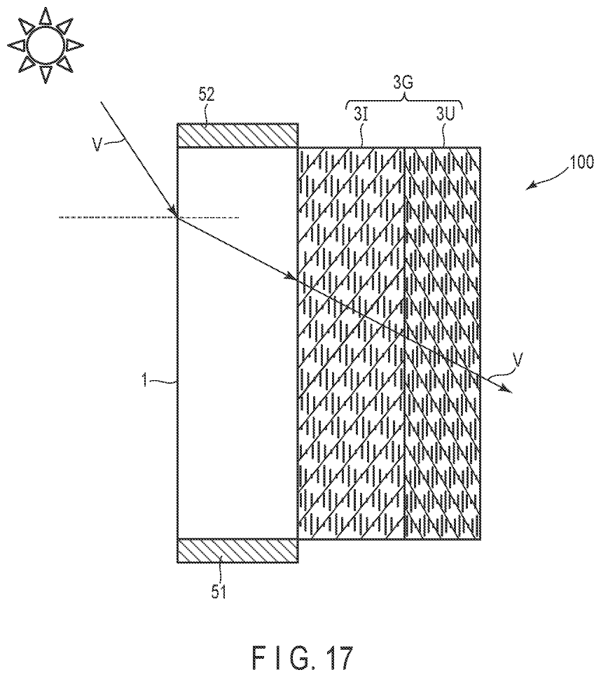

Next, visible light V included in solar light will be described with reference to FIG. 17. The visible light V transmits through the optical waveguide 1 and then enters the second optical element 3I. Since the second spiral pitch P2 is set so as to reflect the infrared ray I as illustrated in FIG. 16A, the second optical element 3I transmits the visible light V with almost no reflection and diffraction. The visible light V transmits through the second optical element 3I and then enters the first optical element 3U. Since the first spiral pitch P1 is set so as to reflect the ultraviolet ray U as illustrated in FIG. 16A, the first optical element 3U transmits the visible light V with almost no reflection and diffraction. Therefore, in the seventh configuration example, the visible light V is not used for power generation.

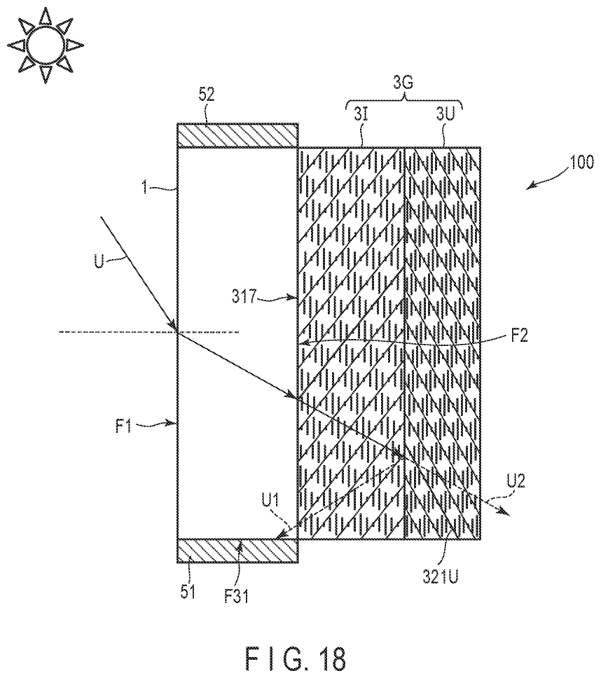

Next, the ultraviolet ray U contained in the solar light will be described with reference to FIG. 18. The ultraviolet ray U transmits through the optical waveguide 1 and then enters the second optical element 3I. The second optical element 3I transmits the ultraviolet ray U with almost no reflection and diffraction. The ultraviolet ray U transmits through the second optical element 3I and then enters the first optical element 3U.

The first optical element 3U reflects the first circularly polarized light U1 of the ultraviolet ray U on the reflective surface 321U toward the optical waveguide 1 and the first solar cell 51. The first optical element 3U transmits the second circularly polarized light U2. The reflected first circularly polarized light U1 enters the inside of the optical waveguide 1 from the second main surface F2, and propagates downward inside the optical waveguide 1 while repeating reflection in the optical waveguide 1. The first solar cell 51 receives the ultraviolet ray U emitted from the lower side surface F31 and generates power.

According to such a seventh configuration example, it is possible to efficiently generate power using the infrared ray I and the ultraviolet ray U. In addition, the solar power generation apparatus 100 transmits most components of the visible light V. Therefore, coloring of the light transmitted through the solar power generation apparatus 100 can be suppressed. In addition, it is possible to suppress a degradation in transmittance of the visible light V in the solar power generation apparatus 100.

In addition, as illustrated in FIG. 16B, the first optical element 3U configured to reflect the ultraviolet ray U is provided between the optical waveguide 1 and the second optical element 3I, so that degradation of the second optical element 3I due to the ultraviolet ray is suppressed.

### Third Embodiment—Eighth Configuration Example

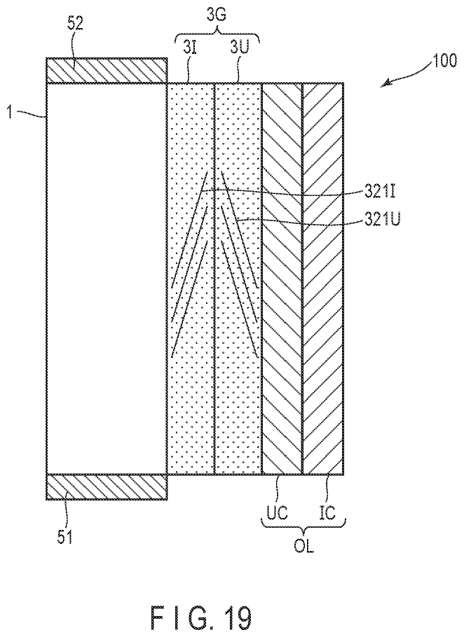

FIG. 19 is a cross-sectional view schematically illustrating the solar power generation apparatus 100 according to an eighth configuration example.

The eighth configuration example illustrated in FIG. 19 is different from the seventh configuration example illustrated in FIG. 16A in that the solar power generation apparatus 100 includes an optical layer OL facing the optical element group 3G. The optical layer OL is located on the indoor side. That is, the optical element group 3G is located between the optical waveguide 1 and the optical layer OL.

The optical layer OL of the eighth configuration example includes an ultraviolet cut layer UC and an infrared cut layer IC. The ultraviolet cut layer UC overlaps the infrared cut layer IC. In the example illustrated in FIG. 19, the ultraviolet cut layer UC is located between the optical element group 3G and the infrared cut layer IC, but the infrared cut layer IC may be located between the optical element group 3G and the ultraviolet cut layer UC.

The details of the ultraviolet cut layer UC are as described in the first embodiment, and the details of the infrared cut layer IC are as described in the second embodiment.

According to such an eighth configuration example, power can be generated using the first circularly polarized light U1 and the second circularly polarized light U2 of the ultraviolet ray U. In addition, power can be generated using the first circularly polarized light I1 and the second circularly polarized light I2 of the infrared ray I. Further, in the solar power generation apparatus 100, transmission of the ultraviolet ray U and the infrared ray I to the interior can be suppressed.

In the eighth configuration example, the case where the optical layer OL includes both the ultraviolet cut layer UC and the infrared cut layer IC has been described, but the optical layer OL may include either the ultraviolet cut layer UC or the infrared cut layer IC.

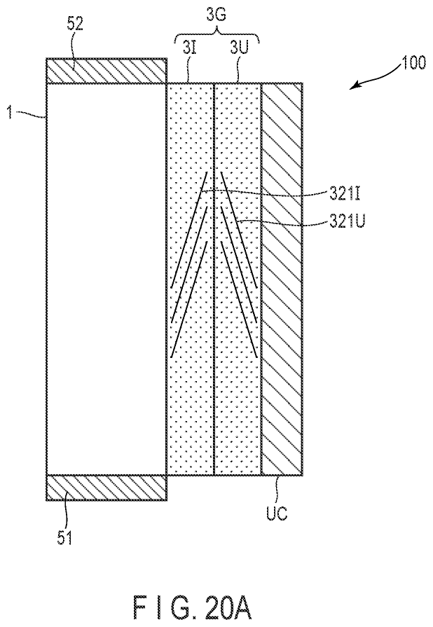

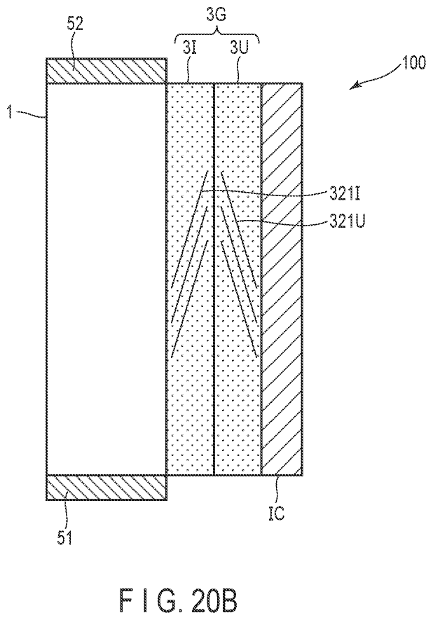

For example, in a modified example illustrated in FIG. 20A, the solar power generation apparatus 100 includes an ultraviolet cut layer UC as an optical layer. The ultraviolet cut layer UC is disposed so as to face the optical element group 3G. As a result, power can be generated using the first circularly polarized light U1 and the second circularly polarized light U2 of the ultraviolet ray U, and transmission of the ultraviolet ray U to the interior can be suppressed.

In addition, in a modified example illustrated in FIG. 20B, the solar power generation apparatus 100 includes an infrared cut layer IC as an optical layer. The infrared cut layer IC is disposed so as to face the optical element group 3G. As a result, power can be generated using the first circularly polarized light I1 and the second circularly polarized light I2 of the infrared ray I, and transmission of the infrared ray I to the interior can be suppressed.

### Third Embodiment—Ninth Configuration Example

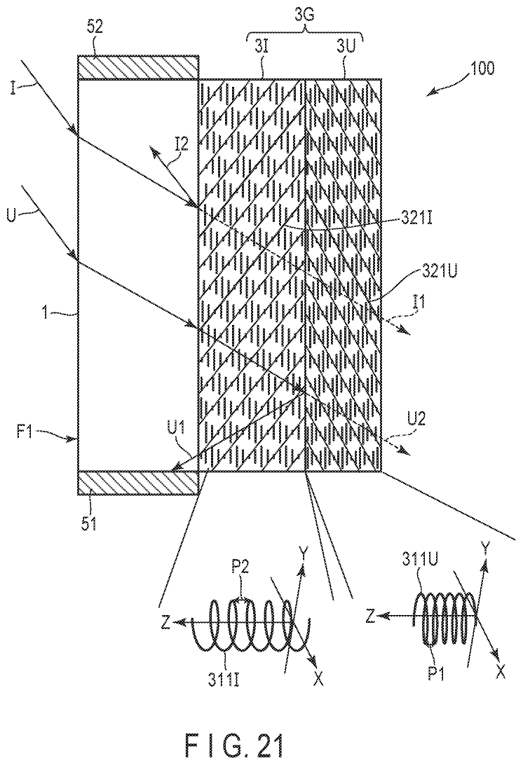

FIG. 21 is a cross-sectional view schematically illustrating the solar power generation apparatus 100 according to a ninth configuration example.

The ninth configuration example illustrated in FIG. 21 is different from the seventh configuration example illustrated in FIG. 16A in that the first optical element 3U has the cholesteric liquid crystal 311U swirled in the first swirling direction, and the second optical element 3I has the cholesteric liquid crystal 311I swirled in the second swirling direction. That is, the cholesteric liquid crystal 311U and the cholesteric liquid crystal 311I swirls in opposite directions to each other.

The first optical element 3U reflects the first circularly polarized light U1 in the first swirling direction and transmits the second circularly polarized light U2 in the second swirling direction in the ultraviolet ray U on the reflective surface 321U. The second optical element 3I reflects the second circularly polarized light I2 in the second swirling direction and transmits the first circularly polarized light I1 in the first swirling direction in the infrared ray I on the reflective surface 321I.

Also in such a ninth configuration example, the same effects as those of the seventh configuration example can be obtained.

### Third Embodiment—Tenth Configuration Example

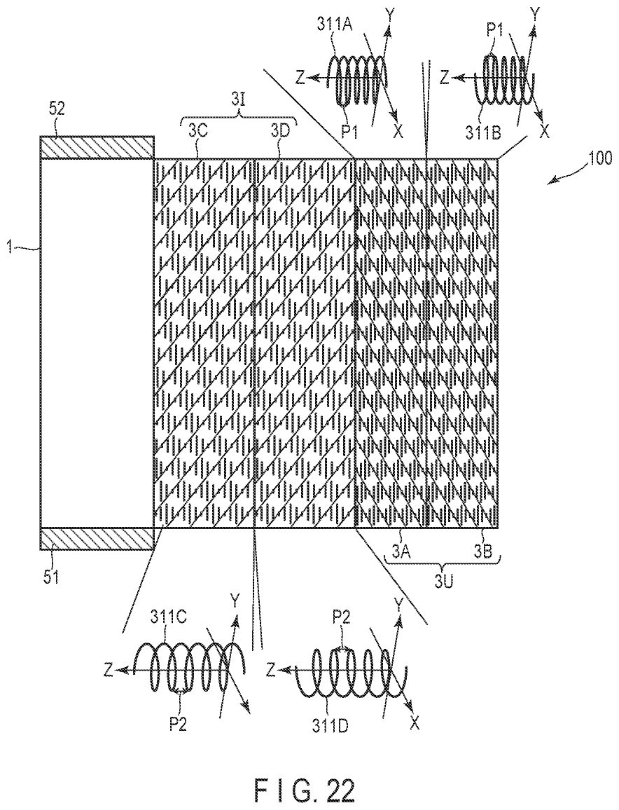

FIG. 22 is a cross-sectional view schematically illustrating the solar power generation apparatus 100 according to a tenth configuration example.

The configuration example 10 illustrated in FIG. 22 is different from the configuration example 7 illustrated in FIG. 16A in that each of the first optical element 3U and the second optical element 3I includes a first layer and a second layer.

That is, the first optical element 3U is configured in the same manner as the third configuration example illustrated in FIG. 10, and includes a first layer 3A having the cholesteric liquid crystal 311A swirled in the first swirling direction and a second layer 3B having the cholesteric liquid crystal 311B swirled in the second swirling direction. The cholesteric liquid crystal 311A and the cholesteric liquid crystal 311B have the same first spiral pitch P1. As a result, the cholesteric liquid crystal 311A of the first layer 3A reflects the first circularly polarized light U1 of the ultraviolet ray U, and the cholesteric liquid crystal 311B of the second layer 3B reflects the second circularly polarized light U2 of the ultraviolet ray U.

The second optical element 3I is configured similarly to the sixth configuration example illustrated in FIG. 15, and includes a first layer 3C having the cholesteric liquid crystal 311C swirled in the first swirling direction and a second layer 3D having the cholesteric liquid crystal 311D swirled in the second swirling direction. The cholesteric liquid crystal 311C and the cholesteric liquid crystal 311D have the same second spiral pitch P2. As a result, the cholesteric liquid crystal 311C of the first layer 3C reflects the first circularly polarized light I1 of the infrared ray I, and the cholesteric liquid crystal 311D of the second layer 3D reflects the second circularly polarized light I2 of the infrared ray I.

According to the tenth configuration example, power can be generated using the first circularly polarized light U1 and the second circularly polarized light U2 of the ultraviolet ray U. In addition, power can be generated using the first circularly polarized light I1 and the second circularly polarized light I2 of the infrared ray I. Further, in the solar power generation apparatus 100, transmission of the ultraviolet ray U and the infrared ray I to the interior can be suppressed.

In each of the eighth configuration example, the ninth configuration example, and the tenth configuration example, as illustrated in FIG. 16B, the first optical element 3U may be provided between the optical waveguide 1 and the second optical element 3I.

As described above, according to the present embodiment, it is possible to provide a solar power generation apparatus capable of efficiently generating power.

In the present specification, the blaze-type has been described as an example of the optical element 3, but the present invention is not limited thereto, and for example, a diffraction layer having a binary pattern may be applied.

In FIG. 1 and the like, a state of light guided through the optical waveguide 1 and the optical element 3 is indicated by an arrow, but this arrow is conceptually indicated. For example, the state of the light reflected by the surface of the optical element 3 of the light guided in the optical waveguide 1 is indicated by an arrow, but actually, a part of the light may seep into the optical element 3, leak out, or remain inside the optical element 3.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solar power generation apparatus, comprising:
an optical waveguide that includes a first main surface, a second main surface opposed to the first main surface, and a lower side surface located on a floor side;
an optical element that faces the second main surface, includes cholesteric liquid crystal, and reflects at least a part of ultraviolet ray of incident light from the first main surface toward the optical waveguide; and
a solar cell that faces the lower side surface and receives the ultraviolet ray to generate power,
wherein the optical element includes a reflective surface angled with respect to a boundary surface between the optical waveguide and the optical element, and
an inclination angle of the reflective surface with respect to the boundary surface is an acute angle toward the solar cell.

2. The solar power generation apparatus according to claim 1, further comprising
an ultraviolet cut layer,
wherein the optical element is located between the optical waveguide and the ultraviolet cut layer.

3. A solar power generation apparatus, comprising:
an optical waveguide that includes a first main surface, a second main surface opposed to the first main surface, and an upper side surface located on a ceiling side;
an optical element that faces the second main surface, includes cholesteric liquid crystal, and reflects at least a part of infrared ray of incident light from the first main surface toward the optical waveguide; and
a solar cell that faces the upper side surface and receives the infrared ray to generate power,
wherein the optical element includes a reflective surface angled with respect to a boundary surface between the optical waveguide and the optical element, and
an inclination angle of the reflective surface with respect to the boundary surface is an acute angle toward the solar cell.

4. The solar power generation apparatus according to claim 3, further comprising
an infrared cut layer,
wherein the optical element is located between the optical waveguide and the infrared cut layer.

5. The solar power generation apparatus according to claim 1, wherein the optical element includes the cholesteric liquid crystal swirled in a first swirling direction, and reflects first circularly polarized light in the first swirling direction.

6. The solar power generation apparatus according to claim 3, wherein the optical element includes the cholesteric liquid crystal swirled in a first swirling direction, and reflects first circularly polarized light in the first swirling direction.

7. The solar power generation apparatus according to claim 1, wherein
the optical element further includes:
a first layer that includes the cholesteric liquid crystal swirled in a first swirling direction and reflects first circularly polarized light in the first swirling direction; and
a second layer that includes the cholesteric liquid crystal swirled in a second swirling direction opposite to the first swirling direction and reflects second circularly polarized light in the second swirling direction.

8. The solar power generation apparatus according to claim 3, wherein
the optical element further includes:
a first layer that includes the cholesteric liquid crystal swirled in a first swirling direction and reflects first circularly polarized light in the first swirling direction; and
a second layer that includes the cholesteric liquid crystal swirled in a second swirling direction opposite to the first swirling direction and reflects second circularly polarized light in the second swirling direction.

9. A solar power generation apparatus, comprising:
an optical waveguide that includes a first main surface, a second main surface opposed to the first main surface, a lower side surface located on a floor side, and an upper side surface located on a ceiling side;
an optical element group that faces the second main surface;
a first solar cell that faces the lower side surface and receives ultraviolet rays of incident light to generate power; and
a second solar cell that faces the upper side surface and receives infrared rays of incident light to generate power,
wherein
the optical element group includes:
a first optical element that includes cholesteric liquid crystal with a first spiral pitch and reflects at least part of incident light via the optical waveguide toward the optical waveguide; and
a second optical element that overlaps the first optical element, includes cholesteric liquid crystal with a second spiral pitch different from the first spiral pitch, and reflects at least a part of incident light via the optical waveguide toward the optical waveguide,
the first optical element includes a first reflective surface angled with respect to a boundary surface between the optical waveguide and the optical element group,
an inclination angle of the first reflective surface with respect to the boundary surface is an acute angle toward the first solar cell,
the second optical element includes a second reflective surface angled with respect to the boundary surface, and
an inclination angle of the second reflective surface with respect to the boundary surface is an acute angle toward the second solar cell.

10. The solar power generation apparatus according to claim 9, further comprising
an optical layer which is at least one of an ultraviolet cut layer and an infrared cut layer,
wherein the optical element group is located between the optical waveguide and the optical layer.

11. The solar power generation apparatus according to claim 9, further comprising
an optical layer in which an ultraviolet cut layer and an infrared cut layer overlap,
wherein the optical element group is located between the optical waveguide and the optical layer.

12. The solar power generation apparatus according to claim 9, wherein
each of the first optical element and the second optical element includes the cholesteric liquid crystal swirled in a first swirling direction, and reflects first circularly polarized light in the first swirling direction.

13. The solar power generation apparatus according to claim 9, wherein
the first optical element includes the cholesteric liquid crystal swirled in a first swirling direction, and reflects first circularly polarized light in the first swirling direction, and
the second optical element includes the cholesteric liquid crystal swirled in a second swirling direction opposite to the first swirling direction, and reflects the second circularly polarized light in the second swirling direction.

14. The solar power generation apparatus according to claim 9, wherein
each of the first optical element and the second optical element includes:
a first layer that includes the cholesteric liquid crystal swirled in a first swirling direction and reflects first circularly polarized light in the first swirling direction; and
a second layer that includes the cholesteric liquid crystal swirled in a second swirling direction opposite to the first swirling direction and reflects second circularly polarized light in the second swirling direction.

15. The solar power generation apparatus according to claim 1, wherein in the optical waveguide, the first main surface is located on an outdoor side, and the second main surface is located on an indoor side.

16. The solar power generation apparatus according to claim 3, wherein in the optical waveguide, the first main surface is located on an outdoor side, and the second main surface is located on an indoor side.

17. The solar power generation apparatus according to claim 9, wherein in the optical waveguide, the first main surface is located on an outdoor side, and the second main surface is located on an indoor side.
